(19) United States
(12) Patent Application Publication
(10) Pub. No.: US 2006/0220265 A1
(43) Pub. Date: Oct. 5, 2006

(54) Alignment mark for semiconductor device, and semiconductor device

(75) Inventors: Takafumi Noda, Shiojiri (JP); Hiroshi Fukuda, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/389,997

(22) Filed: Mar. 27, 2006

(30) Foreign Application Priority Data
Apr. 1, 2005 (JP) 2005-106306

(51) Int. Cl. H01L 23/544

(52) U.S. Cl. 257/797

(57) ABSTRACT

An alignment mark for a semiconductor device is provided. The alignment mark defines a plane pattern and includes a conductive layer embedded in a recessed section provided in an insulation layer, and an oxidation barrier layer provided on the conductive layer, wherein an area occupancy ratio of the recessed section in the plane pattern is 5% or greater.

The entire disclosure of Japanese Patent Application No. 2005-106306, filed Apr. 1, 2005 is expressly incorporated by reference herein.

### BACKGROUND

1. Technical Field

The present invention relates to alignment marks for semiconductor devices, and semiconductor devices.

2. Related Art

In the process of manufacturing semiconductor devices, positional alignment between a wafer and a photomask is an indispensable step, and an error that may be caused at the time of alignment needs to be suppressed to a minimum. For this reason, alignment marks are generally used for correctly superpose a mask pattern to be formed next on a pattern provided on a wafer.

Alignment marks are roughly divided into rough alignment marks that are read by an exposure device at the time of exposing a resist with the exposure device, precision alignment marks, and alignment marks for detecting shifts with an examination device after exposure and development. Accordingly, alignment marks need to be recognized first by an exposure device and an alignment examination device. An example of related art is described in Japanese Laid-open Patent Application JP-A-11-258775.

### SUMMARY

In accordance with some aspects of the present invention, there are provided alignment marks for semiconductor devices, and semiconductor devices including the alignment marks.

(1) In accordance with an embodiment of the invention, an alignment mark for a semiconductor device includes a conductive layer embedded in a recessed section provided in an insulation layer, and an oxidation barrier layer provided on the conductive layer, wherein the alignment mark defines a plane pattern and an area occupancy ratio of the recessed section in the plane pattern is 5% or greater.

The alignment mark for a semiconductor device in accordance with the embodiment of the invention includes a conductive layer embedded in a recessed section provided in an insulation layer, and an oxidation barrier layer provided on the conductive layer. In an aspect of the embodiment, the alignment mark has a plane pattern, and an area occupancy ratio of the recessed section in the plane pattern is 5% or greater. As a result, the alignment mark can be securely recognized by an exposure apparatus, a measurement apparatus such as an examination apparatus and the like.

The alignment mark for a semiconductor device in accordance with an aspect of the embodiment of the invention may be provided inside a ferroelectric memory device. In this case, the ferroelectric memory device may include a contact section, and the recessed section may have a minimum width d₁ that is 0.8 to 2 times a diameter d₂ of the contact section.

(2) A semiconductor device in accordance with another embodiment of the invention includes the alignment mark for a semiconductor device in accordance with the embodiment described above.

The semiconductor device of the present embodiment described above may further include a ferroelectric memory device. In this case, the ferroelectric memory device may include a contact section, and the recessed section may have a minimum width d₁ that is 0.8 to 2 times a diameter d₂ of the contact section.

### BRIEF DESCRIPTION OF THE DRAWINGS

FIG. 1 is a plan view schematically showing an arrangement of alignment marks for a semiconductor device in accordance with an embodiment of the invention.

FIG. 2 is a cross-sectional view schematically showing a semiconductor device including the alignment mark indicated in FIG. 1.

FIG. 3 is an enlarged plan view schematically showing an alignment mark in accordance with an embodiment of the invention.

FIG. 4 is a view schematically showing a cross section taken along a line A-A indicated in FIG. 3.

FIG. 5 is an enlarged plan view schematically showing a modified example of the alignment mark shown in FIG. 1.

FIG. 6 is an enlarged plan view schematically showing a modified example of the alignment mark shown in FIG. 1.

FIG. 7 is an enlarged plan view schematically showing a modified example of the alignment mark shown in FIG. 1.

FIG. 8 is an enlarged plan view schematically showing a modified example of the alignment mark shown in FIG. 1.

FIG. 9 is a cross-sectional view schematically showing a step of a common method for manufacturing a semiconductor device.

FIG. 10 is a cross-sectional view schematically showing a step of the common method for manufacturing a semiconductor device.

FIG. 11 is a cross-sectional view schematically showing a step of the common method for manufacturing a semiconductor device.

### DESCRIPTION OF EXEMPLARY EMBODIMENTS

Preferred embodiments of the present invention are described below with reference to the accompanying drawings.

1. Alignment Mark for Semiconductor Device and Structure of Semiconductor Device

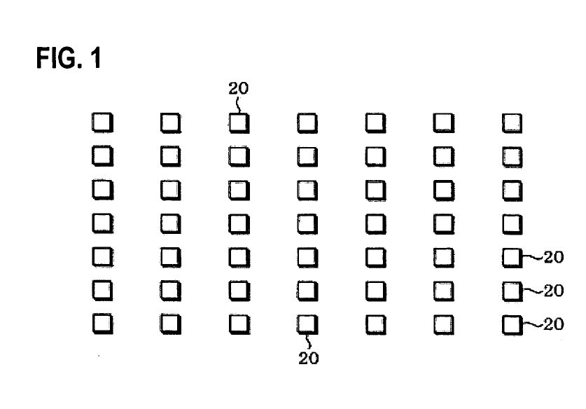

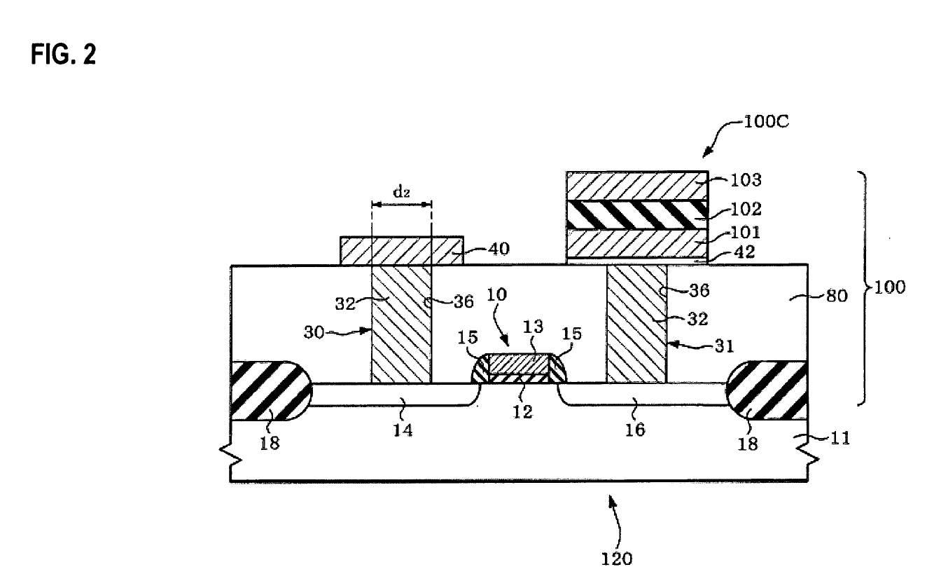

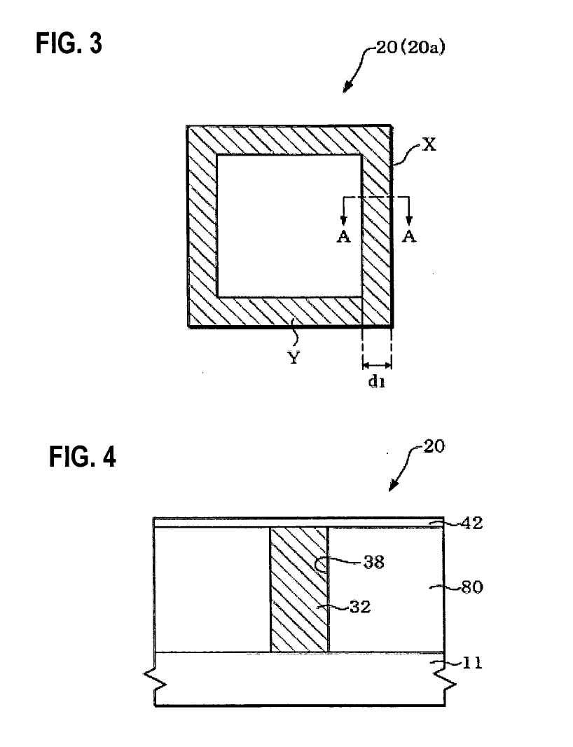

FIG. 1 is a plan view schematically showing an arrangement of alignment marks for semiconductor devices (hereafter also simply referred to as “alignment marks”) 20 in accordance with an embodiment of the invention. FIG. 2 is a cross-sectional view schematically showing a semiconductor device 120 including an alignment mark 20 indicated in FIG. 1. FIG. 3 is an enlarged plan view schematically showing the alignment mark 20 in accordance with the embodiment of the invention. FIG. 4 is a view schematically showing a cross section taken along a line A-A indicated in FIG. 3.

The alignment marks 20 in accordance with the embodiment can be used as alignment marks that are generally used in the manufacturing of semiconductor devices. For example, the alignment marks 20 can be used as rough alignment marks that are read by an exposure apparatus at the time of exposing a resist with the exposure apparatus, precision alignment marks, and alignment marks for detecting shifts with an alignment examination apparatus after exposure and development.

FIG. 1 shows an arrangement of a plurality of alignment marks 20 (20a) that are disposed in a row direction and a column direction. It is noted that the manner of arrangement of the alignment marks 20 is not limited to the above, but any manner of arrangement can be used as long as they can be recognized by a measurement apparatus. Also, the alignment marks 20 can be used in the process for manufacturing a semiconductor device 120 that includes a ferroelectric memory device 100 shown in FIG. 2. Accordingly, the alignment mark 20 can be provided within the semiconductor device 120 (within the ferroelectric memory device 100).

The alignment mark 20 of the present embodiment includes, as shown in FIG. 4, a conductive layer 32 embedded in a recessed section 38 provided in an insulation layer 80, and an oxidation barrier layer 42 provided on the conductive layer 32. In FIG. 4, the oxidation barrier layer 42 is provided on the conductive layer 32 and the insulation layer 80. Also, as shown in FIG. 3, the alignment mark 20 (20a) has a plane pattern that may be in a ring shape.

In the alignment mark 20 of the present embodiment, the area occupancy ratio of the recessed section 38 in the plane pattern is 5% or greater. It is noted here that the “area occupancy ratio of the recessed section 38 in the plane pattern of the alignment mark 20” means to be, as shown in FIG. 3, a ratio of the area of a region Y (a hatched region, i.e., the recessed section 38) to the area of a region surrounded by a line X (i.e., an inner region surrounded by the line X) of the plane pattern of each of the alignment marks 20. In other words, the “area occupancy ratio (%) of the recessed section 38 in the plane pattern of the alignment mark 20” is expressed by “the area of the region Y in the plane pattern/the area of an inner region surrounded by the line X of the plane pattern×100” (see FIG. 3). It is noted that, in FIG. 3, the line X corresponds to an outer circumference of the region Y shown in a solid line.

With the alignment mark 20 in accordance with the present embodiment, if the area occupancy ratio of the recessed section 38 in the plane pattern is less than 5%, there is a possibility that the mark 20 may not be recognized by an exposure apparatus or a measurement apparatus such as an examination apparatus.

The alignment mark 20 in accordance with the present embodiment may be composed of the same material as that of a contact section 30 provided within the ferroelectric memory device 100 shown in FIG. 2. More concretely, the alignment mark 20 and the contact section 30 may be disposed in the same insulation layer 80, and may include the conductive layers 32 composed of the same material. Also, the alignment mark 20 of the present embodiment and the contact section 30 may be formed in the same process.

Further, an oxidation barrier layer 42 (see FIG. 2) disposed between a ferroelectric capacitor 100C and the insulation layer 80 of the ferroelectric memory device 100 can be formed by a common process for forming the oxidation barrier layer 42 included in the alignment mark 20 (see FIG. 4). In this case, both of the oxidation barrier layers 42 can be composed of the same material. It is noted that FIG. 2 shows an example in which an oxidation barrier layer is not provided in the contact section 30. However, oxidation barrier layers 42 of the same composition may be formed in both of the alignment mark 20 and the contact section 30.

The conductive layer 32 may be composed of a high-melting point metal, such as, for example, tungsten. The oxidation barrier layer 42 has a function to prevent oxidation of the conductive layer 32. The oxidation barrier layer 42 may be formed from, for example, TiN, TiAlN, Al₂O₃, a laminated body of Ti and TiN, or the like.

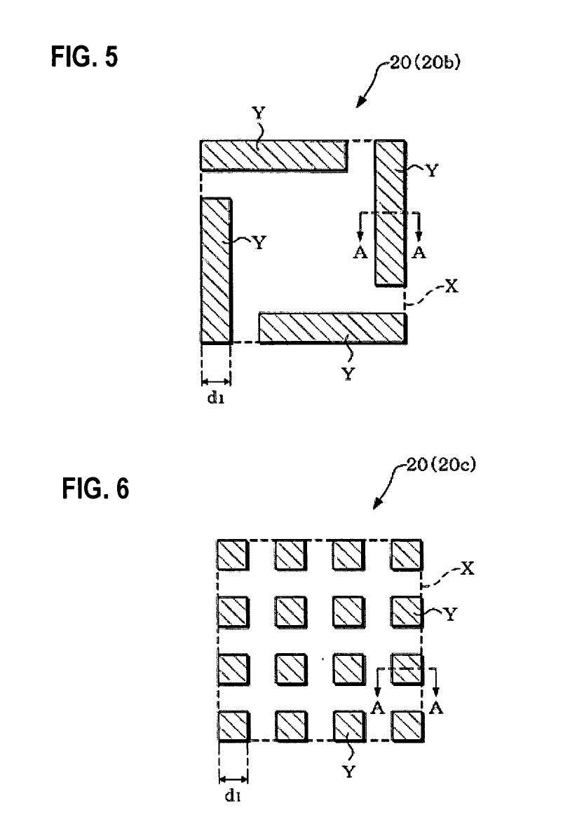

The minimum width d₁ (see FIG. 3) of the recessed section 38 of the alignment mark 20 may preferably be 0.8 to 2 times the diameter d₂ (see FIG. 2) of the contact section 30 (in other words, d₁=0.8 d₂ through 2 d₂), and more preferably, d₁=d₂. When the minimum width d₁ of the recessed section 38 of the alignment mark 20 is 0.8 to 2 times the diameter d₂ of the contact section 30, the conductive layer 32 of the alignment mark 20 can be formed by embedding a conductive material in the recessed section 38, in the same step as the step of embedding the conductive material in an opening section 36 to form the conductive layer 32 of the contact section 30. Moreover, the minimum width d₁ of the recessed section 38 of the alignment mark 20 may preferably be about the same as the diameter d₂ of the contact section 30. It is noted that the relation between the minimum width d₁ of the recessed section 38 of the alignment mark 20 and the size of the diameter d₂ of the contact section 30 can be similarly applied to alignment marks 20b-20e shown in FIG. 5 through FIG. 8.

FIG. 5 through FIG. 8 are enlarged plan views schematically showing modified examples (20b-20e) of the alignment mark 20 shown in FIG. 1. Also, in the alignment marks 20b-20e shown in FIG. 5 through FIG. 8, each of their cross sections taken along a line A-A is generally the same as the cross section (see FIG. 4) of the alignment mark 20a shown in FIG. 3. In other words, in each of the alignment marks 20b-20e shown in FIG. 5 through FIG. 8, the hatched portion corresponds to the region Y (the recessed section 38, in other words, the portion where the conductive layer 32 is disposed). In other words, the conductive layer 32 is embedded in the recessed section 38 in each of the alignment marks 20b-20e shown in FIG. 5 through FIG. 8, like the alignment mark 20a shown in FIG. 3. Also, the alignment marks 20b-20e shown in FIG. 5 through FIG. 8 can be arranged in a manner shown in FIG. 1, like the alignment mark 20a shown in FIG. 3. It is noted that the line X is shown by a dotted line in each of FIG. 5 through FIG. 8.

The alignment mark 20b shown in FIG. 5 has a plane pattern in a shape in which areas adjacent to the four corners of the plane pattern of the alignment mark 20a shown in FIG. 3 are removed.

The alignment mark 20c shown in FIG. 6 has a plane pattern in a shape in which square regions Y (corresponding to the conductive layers 32, and the recessed sections 38) are disposed in a lattice arrangement.

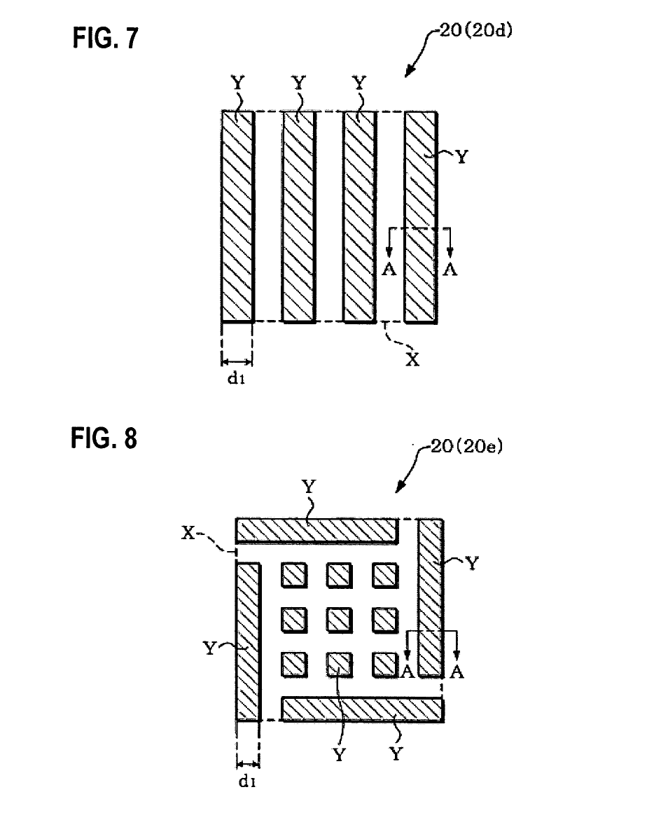

The alignment mark 20d shown in FIG. 7 has a plane pattern in a shape in which rectangular regions Y (corresponding to the conductive layers 32, and the recessed sections 38) are disposed in stripes.

The alignment mark 20e shown in FIG. 8 has a plane pattern in a shape in which a pattern similar to the plane pattern of the alignment mark 20c shown in FIG. 6 is disposed inside the plane pattern of the alignment mark 20b shown in FIG. 5.

Each of the alignment marks 20b-20e shown in FIG. 5 through FIG. 8, other than the portions described above, has a structure similar to that of the alignment mark 20a described above, and has similar action and effects thereof.

The ferroelectric memory device 100 includes a transistor 10 and a ferroelectric capacitor 100C. It is noted that, although a 1T/1C type memory cell is described in the present embodiment, the invention is not limited in its application to a 1T/1C type memory cell. Also, the ferroelectric memory device 100 includes contact sections 30 and 31 provided in an insulation layer 80. The contact section 30 is disposed on a first impurity region 14. The contact section 31 is formed on a second impurity region 16.

The ferroelectric capacitor 100C is mainly formed from a first electrode 101, a ferroelectric film 102 formed on the first electrode 102, and a second electrode 103 formed on the ferroelectric film 102. Also, the ferroelectric capacitor 100C is disposed on the contact section 31.

The ferroelectric film 102 includes ferroelectric material. The ferroelectric material may have a perovskite type crystal structure, and may be expressed by a general formula of A_{1-b}B₁₋ₐXₐO₃. A in the formula includes Pb. B is composed of at least one of Zr and Ti. X is composed of at least one of V, Nb, Ta, Cr, Mo, and W. The ferroelectric film 102 can be composed of a known material that can be used as a ferroelectric film, and for example, (Pb(Zr,Ti)₃) (PZT), SrBi₂Ta₂O₉ (SBT), and (Bi,La)₄Ti₃O₂ (BLT) can be enumerated as the material. The ferroelectric film 102 can be formed by high-temperature sintering of a film formed by, for example, a sol-gel method.

The transistor 10 includes a gate dielectric layer 12, a gate conductive layer 13 formed on the gate dielectric layer 12, and first and second impurity regions 14 and 16 defining source/drain regions.

2. Action and Effect

The alignment mark 20 in accordance with the present embodiment can be securely recognized by an exposure apparatus and a measurement apparatus such as an examination apparatus because the area occupancy ratio of the recessed section 38 in a plane pattern of the alignment mark 20 is 5% or greater. To describe action and effect of the alignment mark 20 for a semiconductor device in accordance with the present embodiment in greater detail, first, a general process for forming a contact section provided in a ferroelectric memory device 120 and an alignment mark in a common process in manufacturing a semiconductor device is described.

2.1. General Process for Manufacturing Contact Section and Alignment Mark

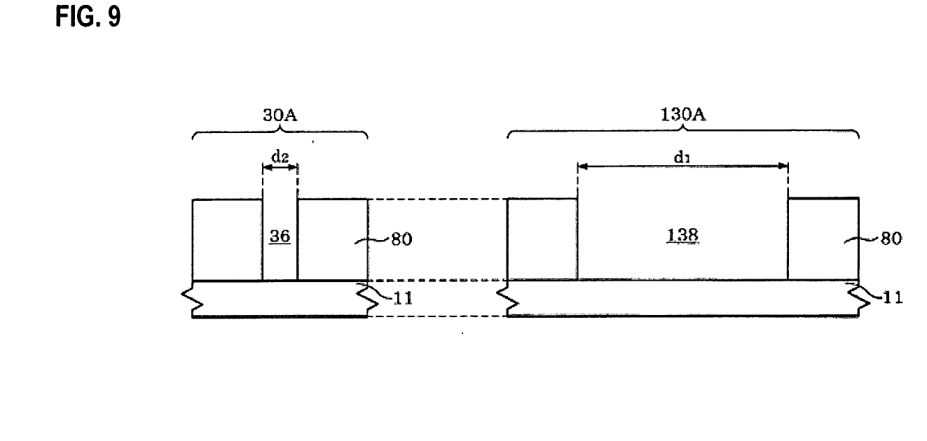

In FIG. 9 through FIG. 11, a section “30A” indicates a forming region of a contact section 30 shown in FIG. 2, and a section “130A” indicates a forming region of an ordinary alignment mark 130.

First, as shown in FIG. 9, an opening section 36 is formed in the forming region 30A of the contact section 30, and a recessed section 138 is formed in the forming region 130A of the alignment mark 130 in an insulation layer 80, respectively, by, for example, a photolithography method. For the ordinary alignment mark, the width of the recessed section 138 is normally at least five times larger than the diameter of the opening section 36. For example, when the diameter of the opening section 36 (the diameter of the contact section 30 to be formed later) is 0.6 μm, the width of the recessed section 138 may be 3 μm.

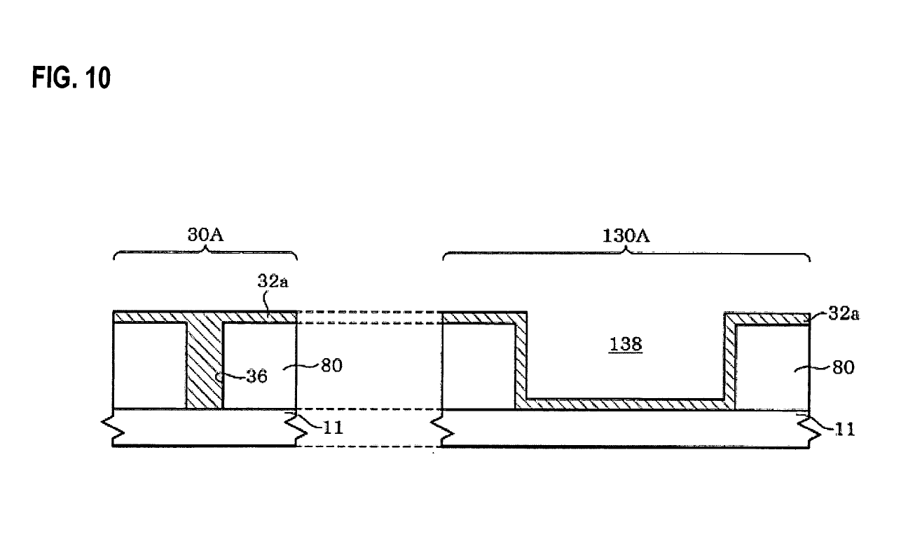

Next, as shown in FIG. 10, a conductive layer 32a is embedded in the opening section 36 by, for example, a sputter method or a CVD method. The conductive layer 32a is composed of a conductive material for forming a conductive layer that later becomes to be a contact plug, and may be composed of tungsten or the like, as described above. By this step, the conductive layer 32a is formed on the surface of the recessed section 138. However, because the width of the recessed section 138 is substantially greater than the diameter of the opening section 36, the recessed section 138 is not embedded with the conductive layer 32a, and a step difference remains in the recessed section 138. Then, the conductive layer 32a on the insulation layer 80 is removed by, for example, a CMP method.

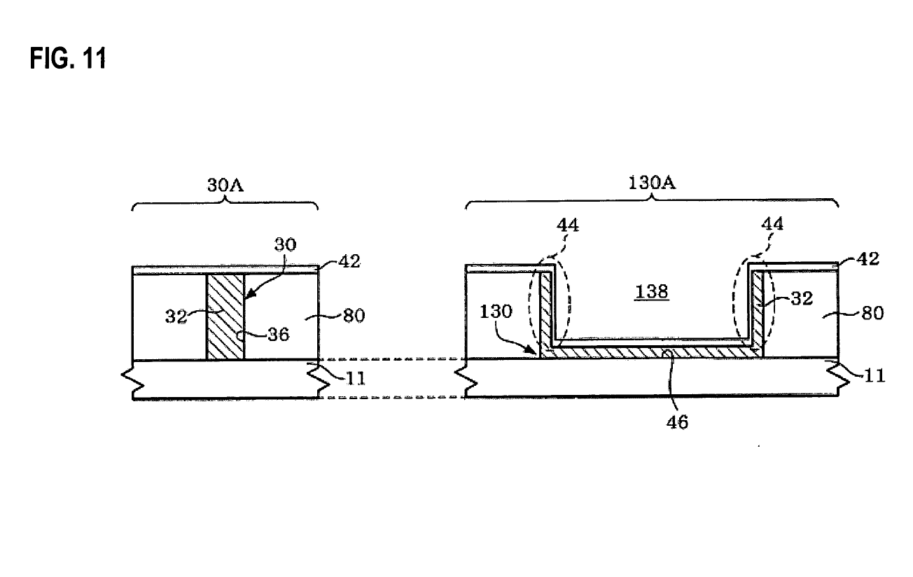

Then, as shown in FIG. 11, an oxidation barrier layer 42 is formed on the conductive layer 32 and the insulation layer 80. It is noted that the oxidation barrier layer 42 is removed in the forming region of the contact section 30. By the process described above, the contact section 30 and the alignment mark 130 are formed in the semiconductor device 120. It is noted here that, in the forming region of the alignment mark 130A, the oxidation barrier layer 42 is formed on an upper surface of the insulation layer 80 and on side walls 44 and bottom surface 46 of the recessed section 138 (see FIG. 11). However, because the oxidation barrier layer 42 is generally formed by sputtering, the film thickness of the oxidation barrier layer 42 formed on the side walls 44 of the recessed section 130 is smaller than the film thickness of the oxidation barrier layer 42 formed on the upper surface of the insulation layer 80.

On the other hand, in manufacturing a ferroelectric memory device, a ferroelectric film 102 (see FIG. 2) is generally formed by sintering with a high-temperature heat treatment. The temperature of the high-temperature heat treatment is generally 400 to 750° C. or higher. In contrast, as described above, in the ordinary alignment mark 130, the film thickness of the oxidation barrier layer 42 formed on the side walls 44 of the recessed section 138 is small (see FIG. 11), such that the oxidation barrier layer 42 on the side walls 44 cannot demonstrate its oxidation barrier function, and the conductive layer 32 composed of a high melting point metal such as tungsten is oxidized at the side walls 44 of the recessed section 138 in the high-temperature heat treatment for sintering the ferroelectric film 102. As a result, the shape of the alignment mark 130 near the side walls 44 of the recessed section 138 may be damaged. Consequently, the alignment mark 130 may not be recognized by a measurement apparatus.

2.2. Action and Effect of Alignment Mark of the Embodiment

In contrast, the alignment mark 20 in accordance with the present embodiment, as shown in FIG. 3 and FIG. 4, includes the conductive layer 32 embedded in the recessed section 38 and the oxidation barrier layer 42 provided on the conductive layer 32, wherein the area occupancy ratio of the recessed section 38 in the plane pattern is 5% or greater. By this, the conductive layer 32 is embedded in the recessed section 38, and the oxidation barrier layer 42 prevents the conductive layer 32 from being oxidized. Accordingly, oxidation of the conductive layer 32 can be securely prevented in a high-temperature heat treatment for sintering the ferroelectric film 102. For this reason, the shape of the alignment mark 130 near the side walls 44 of the recessed section 138 is not damaged. Furthermore, according to the alignment mark 20 of the present embodiment, because the area occupancy ratio of the recessed section 38 in the plane pattern is 5% or greater, the plane pattern of the alignment mark 20 of the present embodiment can be securely recognized by an exposure apparatus and a measurement apparatus such as an examination apparatus.

Also, the alignment mark 20 in accordance with the present embodiment may be provided within the semiconductor device 120 that includes the ferroelectric memory device 100, and the ferroelectric memory device 100 includes the contact section 30, wherein the minimum width d₁ of the recessed section 38 is 0.8 to 2 times the diameter d₂ of the contact section 30. Therefore, the conductive layer 32 can be securely embedded in the recessed section 38 for forming the alignment mark 20 in the same step as the step of embedding the conductive layer 32 in the contact section 30 included in the ferroelectric memory device 100. By this, the alignment mark 20 with the conductive layer 32 having an upper surface being covered by the oxidation barrier layer 42 can be obtained. As a result, the alignment mark 20 in which oxidation of the conductive layer 32 is securely prevented by the oxidation barrier layer 42 can be obtained. According to the alignment mark 20, because oxidation of the conductive layer 32 is securely prevented by the oxidation barrier layer 42, the shape of the conductive layer 32 would not be changed by its oxidation in a high-temperature heat treatment for sintering the ferroelectric film 102. Therefore, the alignment mark 20 in accordance with the present embodiment can be more accurately recognized by an exposure apparatus and a measurement apparatus such as an examination apparatus when it is used in manufacturing, for example, the ferroelectric memory device 100.

The embodiments of the invention are described above in detail. However, those skilled in the art should readily understand that many modifications can be made without substantially departing from the novel matter and effects of the invention. Accordingly, those modified examples are also included in the scope of the invention.

What is claimed is:

1. An alignment mark for a semiconductor device, the alignment mark defining a plane pattern, the alignment mark comprising:
a conductive layer embedded in a recessed section provided in an insulation layer; and
an oxidation barrier layer provided on the conductive layer,
wherein an area occupancy ratio of the recessed section in the plane pattern is 5% or greater.

2. An alignment mark for a semiconductor device according to claim 1 provided in a ferroelectric memory device.

3. An alignment mark for a semiconductor device according to claim 2, wherein the ferroelectric memory device includes a contact section, and the recessed section has a minimum width d₁ that is 0.8 to 2 times a diameter d₂ of the contact section.

4. A semiconductor device comprising the alignment mark for a semiconductor device recited in claim 1.

5. A semiconductor device according to claim 4, further comprising a ferroelectric memory device.

6. A semiconductor device according to claim 5, wherein the ferroelectric memory device includes a contact section, and the recessed section has a minimum width d₁ that is 0.8 to 2 times a diameter d₂ of the contact section.
